(19) United States
(12) Patent Application Publication
(10) Pub. No.: US 2007/0096098 A1
(43) Pub. Date: May 3, 2007

(54) CONDUCTIVE STRUCTURE, MANUFACTURING METHOD FOR CONDUCTIVE STRUCTURE, ELEMENT SUBSTRATE, AND MANUFACTURING METHOD FOR ELEMENT SUBSTRATE

(75) Inventors: Nobuaki Ishiga, Kumamoto (JP); Kensuke Nagayama, Kumamoto (JP); Kenichi Miyamoto, Kumamoto (JP); Tadaki Nakahori, Kumamoto (JP); Kazunori Inoue, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/551,301

(22) Filed: Oct. 20, 2006

(30) Foreign Application Priority Data
Oct. 31, 2005 (JP) 2005-315983

(51) Int. Cl. H01L 29/04

(52) U.S. Cl. 257/59

(57) ABSTRACT

A conductive structure includes a laminated structure of an upper layer and a lower layer. The lower layer is formed of an aluminum alloy containing at least one kind of Group 8 elements in periodic table. The upper layer is laminated on the lower layer and formed of an aluminum alloy containing at least one kind of Group 8 elements in periodic table and nitrogen.

### BACKGROUND OF THE INVENTION

1. Field of the Invention

The present invention generally relates to a conductive structure, a manufacturing method for a conductive structure, an element substrate, and a manufacturing method for an element substrate. More particularly, the present invention relates to a conductive structure such as an electrode or line connected to a TFT (Thin Film Transistor) formed on a substrate, a manufacturing method for the conductive structure, an element substrate having the conductive structure, and a manufacturing method for the element substrate.

2. Description of the Related Art

Recently, various electronic equipment such as a mobile telephone, a portable information terminal, an electronic organizer and a portable television has a display such as a liquid crystal display.

There are various types of liquid crystal displays. TN (Twisted Nematic) mode and STN (Super Twisted Nematic) mode are known as operation mode, and passive matrix and active matrix are known as driving method, for liquid crystal displays.

A normal TFT liquid crystal display employs the TN mode and the active matrix method. Such a TFT liquid crystal display is used in a variety of electronic equipment because of its light-weight, low-profile, clear display, and long-time operating characteristics.

In a TFT liquid crystal display, a liquid crystal layer is interposed between a counter substrate and a TFT array substrate. On the counter substrate, a common electrode is formed all over the inner surface. On the inner surface of the TFT array substrate, a TFT and a pixel electrode are arranged in matrix in each pixel. The counter substrate and the TFT array substrate are placed oppositely with the inner surfaces facing each other. The TFT is a three-terminal switch that is composed of a semiconductor layer such as amorphous silicon having a gate electrode, a source electrode, and a drain electrode. The drain electrode electrically connects between the semiconductor layer and the pixel electrode.

A transparent conductive material such as ITO (Indium Tin Oxide) having high light transmittance is used for the pixel electrode. Aluminum or aluminum alloy having low resistance is used for the drain electrode or the gate electrode. In this structure, however, due to direct contact between the aluminum or aluminum alloy and the ITO, an oxide layer can be formed along a boundary between the pixel electrode and the drain electrode. In order to prevent the oxide layer from being formed, Japanese Unexamined Patent Application Publication No. 04-253342 (referred to herein as a patent document 1) proposes a technique of placing a high melting point metal such as Chromium (Cr) between the pixel electrode and the drain electrode.

However, this technique requires an additional process of a film deposition step, a patterning step and so on to form the high melting point metal such as Chromium (Cr), which increases manufacturing costs.

As a technique that eliminates the process of forming the high melting point metal, Japanese Unexamined Patent Application Publication No. 2004-214606 (referred to herein as a patent document 2) proposes a technique of directly contacting a drain electrode formed of an aluminum alloy containing nickel (Ni) with a pixel electrode formed of ITO to thereby establish an electrical connection. If the drain electrode is formed of an aluminum alloy containing nickel (Ni), an oxide layer is not formed along a boundary between the pixel electrode and the drain electrode.

Normally, a process of forming a TFT array substrate deposits a metal material that is a material of an electrode or line on a transparent substrate. Then, photoresist is coated on the metal layer, and further light-exposed and developed for patterning using an organic alkaline developer, for example, and thus dissolved. Further, etching is performed and the photoresist is stripped.

However, because an aluminum alloy containing a Group 8 element in the periodic table such as nickel (Ni) has a very low resistance to an alkaline solution, if an electrode or line is formed of an aluminum alloy containing nickel (Ni), a metal film for an electrode or line that is deposited on a substrate can be dissolved during development. This causes a significant decrease in processing accuracy of an electrode or line.

### SUMMARY OF THE INVENTION

According to an aspect of the present invention, there is provided a conductive structure including a laminated structure of an upper layer and a lower layer, the lower layer formed of an aluminum alloy containing at least one kind of Group 8 elements in periodic table, and the upper layer laminated on the lower layer and formed of an aluminum alloy containing at least one kind of Group 8 elements in periodic table and nitrogen.

Laminating the upper layer formed of an aluminum alloy which contains at least one kind of Group 8 elements in the periodic table and nitrogen on the lower layer formed of an aluminum alloy which contains at least one kind of Group 8 elements in the periodic table enables formation of a conductive structure having high alkali resistance and high processing accuracy with a simple structure.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing the structure of main parts of a TFT array substrate according to a first embodiment of the invention;

FIG. 2 is a sectional view along line A-A in FIG. 1 showing the structure of main parts of a TFT array substrate according to the first embodiment of the invention;

FIGS. 3A and 3B are a plan view and a sectional view along line B-B in FIG. 3A, respectively, showing a connection of a source line and a source terminal;

FIGS. 4A and 4B are a plan view and a sectional view along line C-C in FIG. 4A, respectively, showing a connection of a gate line and a gate terminal;

FIG. 5 is a manufacturing flow of a TFT array substrate according to the first embodiment of the invention;

FIG. 6 is a plan view showing the structure of main parts of a TFT array substrate according to a second embodiment of the invention;

FIG. 7 is a sectional view along line D-D in FIG. 6 showing the structure of main parts of a TFT array substrate according to the second embodiment of the invention;

FIG. 8 is a view showing the reflectance of a conductive structure according to an embodiment of the invention and the reflectance of a metal film generally used in an electrode or a line;

FIG. 9 is a plan view showing the structure of main parts of a TFT array substrate according to a third embodiment of the invention;

FIG. 10 is a sectional view along line E-E in FIG. 9 showing the structure of main parts of a TFT array substrate according to the third embodiment of the invention;

FIG. 11 is a plan view showing the structure of main parts of a TFT array substrate according to a fourth embodiment of the invention;

FIG. 12 is a sectional view along line F-F in FIG. 11 showing the structure of main parts of a TFT array substrate according to the fourth embodiment of the invention;

FIGS. 13A and 13B are a plan view and a sectional view along line G-G in FIG. 13A, respectively, showing a connection of a source line and a source terminal;

FIGS. 14A and 14B are a plan view and a sectional view along line H-H in FIG. 14A, respectively, showing a connection of a gate line and a gate terminal; and

FIG. 15 is a manufacturing flow of a TFT array substrate according to the fourth embodiment of the invention.

### PREFERRED EMBODIMENT OF THE INVENTION

### First Embodiment

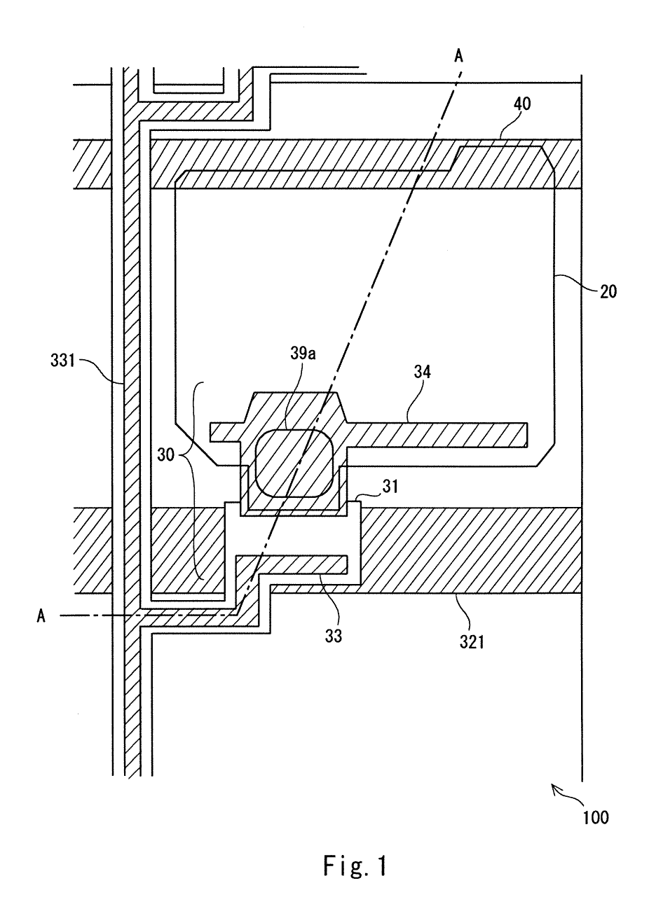

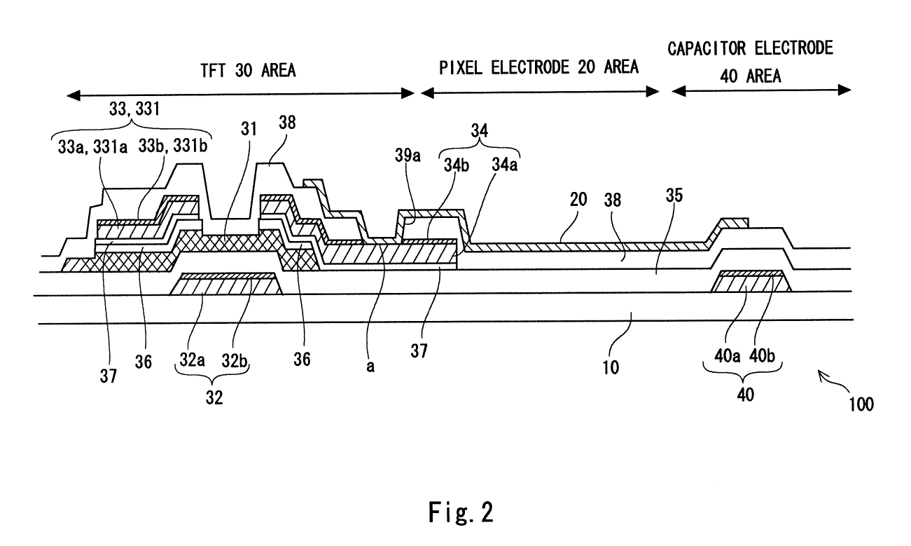

The structure of a TFT array substrate according to a first exemplary embodiment of the present invention is described hereinafter with reference the drawings. FIG. 1 is a plan view showing the structure of main parts of the TFT array substrate according to the first embodiment. FIG. 2 is a sectional view along line A-A in FIG. 1 showing the structure of main parts of the TFT array substrate according to the first embodiment.

As shown in FIGS. 1 and 2, in the TFT array substrate 100, a pixel electrode 20 and a TFT 30 as a switching device are formed in matrix on each pixel on a rectangular transparent substrate 10 formed of glass, polycarbonate, acrylic resin or the like. The inner surface of the TFT array substrate 100 where the TFT 30 and the pixel electrode 20 are arranged in matrix on each pixel is placed opposite to the inner surface of a counter substrate (not shown) where a common electrode (not shown) is formed all over the inner surface. Further, a liquid crystal layer is interposed between the TFT array substrate 100 and the counter substrate. A TFT liquid crystal display (not shown) is thereby produced.

The TFT 30 serves as a switch which can be turned on and off according to each pixel electrode 20. The TFT 30 is turned on according to a signal from a driver (not shown), and a driver supplies a drive voltage to the pixel electrode 20, and the alignment of liquid crystals are changed between the pixel electrode 20 and a common electrode (not shown), thereby controlling the transmission of light through the TFT liquid crystal display.

As shown in FIG. 1, a plurality of the pixel electrode 20, the TFT 30 and so on are arranged in matrix above the transparent substrate 10, thereby constituting the TFT array substrate 100. In FIG. 1, electrodes 32, 33, 34 of the TFT 30, lines 321 and 331 connected to the electrodes 32 and 33, and a capacitor electrode 40 are hatched for convenience.

As shown in FIG. 2, the structure of the main parts of the TFT array substrate 100 are described hereinafter, for each of a TFT 30 area, a pixel electrode 20 area, and a capacitor electrode 40 area.

The TFT 30 area shown in FIG. 2 is described hereinafter with reference to the drawings.

As shown in FIGS. 1 and 2, the TFT 30 is a three-terminal switch composed of a semiconductor layer 31 such as amorphous silicon, which has a gate electrode 32 as a scan electrode, a source electrode 33 as a signal electrode, and a drain electrode 34.

As shown in FIG. 1, the gate electrode 32 is connected to the gate line 321 that is formed between the pixel electrodes 20, and the source electrode 33 is connected to the source line 331 that is also formed between the pixel electrodes 20. As shown in FIG. 1, the gate line 321 and the source line 331 cross each other. As shown in FIG. 2, an insulation layer 35 is formed between the semiconductor layer 31 and the gate electrode 32.

As shown in FIG. 2, an ohmic contact layer 36 such as n+amorphous silicon and a barrier metal 37 are laminated on another between the semiconductor layer 31 and the source electrode 33. Similarly, the ohmic contact layer 36 such as n+amorphous silicon and the barrier metal 37 are laminated on another between the semiconductor layer 31 and the drain electrode 34. As shown in FIG. 2, an insulation layer 38 as a passivation layer is formed between the source electrode 33 and the drain electrode 34. The insulation layer 38 is also formed on the source electrode 33 and the drain electrode 34.

As shown in FIGS. 1 and 2, the pixel electrode 20 is formed above the drain electrode 34 with the insulation layer 38 interposed therebetween in the part of the TFT 30 area which is close to the pixel electrode 20 area. The pixel electrode 20 is electrically connected to the drain electrode 34 in a contact hole 39a that is created in the insulation layer 38. Thus, the pixel electrode 20 is connected to the TFT 30 through the drain electrode 34. The portion where the pixel electrode 20 and the drain electrode 34 are electrically connected is referred to as a connection a.

The gate electrode 32, the source electrode 33, the drain electrode 34, the gate line 321 and the source line 331 as the conductive structure are respectively formed of laminated structures of upper layers 32b, 33b, 34b, 321b, and 331b and lower layers 32a, 33a, 34a, 321a and 321b. These structures are described in further detail later.

The pixel electrode 20 area shown in FIG. 2 is described hereinafter with reference to the drawings.

As shown in FIG. 1, the pixel electrode 20 is formed in a rectangular shape in a pixel which is surrounded by the gate lines 321 and the source lines 331. In order to prevent the detachment of the pixel electrode 20, the four corners of the pixel electrode 20 may be removed as shown in FIG. 1.

As shown in FIG. 2, the pixel electrode 20 is formed above the insulations layers 35 and 38 that are formed above the transparent substrate 10. The pixel electrode 20 may be formed of a material which contains at least one kind of metal selected from indium oxide, tin oxide, and zinc oxide.

The capacitor electrode 40 is described hereinafter.

As shown in FIGS. 1 and 2, the capacitor electrode 40 is formed substantially parallel to the gate line 322 on the transparent substrate 10. As shown in FIG. 1, when seeing through the TFT array substrate 100 from above, the capacitor electrode 40 overlaps with a part of the pixel electrode 20.

The capacitor electrode 40 as a conductive structure has a laminated structure composed of the upper layer 40b and the lower layer 40a. This structure is detailed later.

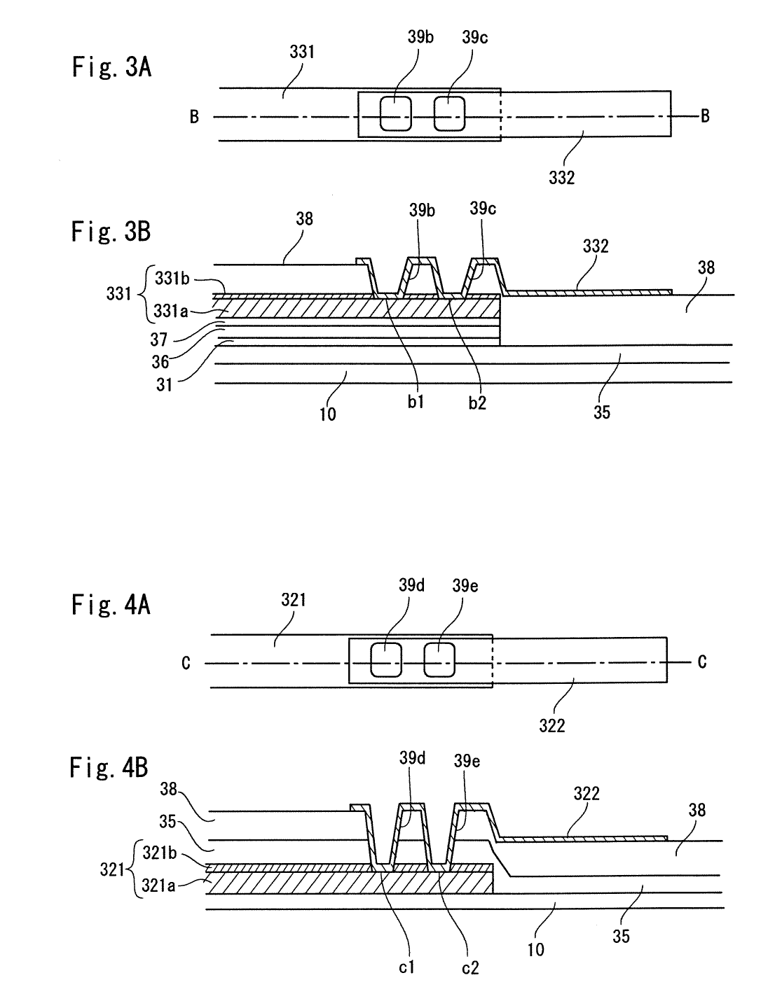

The structure of a source terminal 332 which is placed at an end of the source line 331 is described below. FIGS. 3A and 3B show a connection of the source line and the source terminal. FIG. 3A is a plan view, and the FIG. 3B is a sectional view along line B-B of FIG. 3A.

The source terminal 332 may be placed at one end of the TFT array substrate 100. The source terminal 332 may be connected to an external driver (not shown) through a flexible printed board (not shown) and receive a data signal output from the driver.

As shown in FIGS. 3A and 3B, the source line 331 has a laminated structure which is formed on the insulation layer 35, the semiconductor layer 31, the ohmic contact layer 36, and the barrier metal 37 that are deposited on the transparent substrate 10. The source terminal 332 is electrically connected to the source line 331 in contact holes 39b and 39c that are formed in the insulation layer 38. The portions where the source line 331 and the source terminal 332 are electrically connected are referred to as connections b1 and b2. The source terminal 332 is deposited at the same time as the pixel electrode 20. The source terminal 332 may be formed of a material which contains at least one kind of metal selected from indium oxide, tin oxide, and zinc oxide, just like the pixel electrode 20. As shown in FIG. 3B, a flat part of the source terminal 332 which is formed on the insulation layer 38 serves as a pad that is actually connected to a flexible printed board (not shown).

The source line 331 as a conductive structure has a laminated structure composed of the upper layer 331b and the lower layer 331a. This structure is detailed later.

The structure of a gate terminal 322 which is placed at an end of the gate line 321 is described below. FIGS. 4A and 4B show a connection of the gate line and the gate terminal. FIG. 4A is a plan view, and the FIG. 4B is a sectional view along line C-C of FIG. 4A.

The gate terminal 322 may be placed at one end of the TFT array substrate 100. The gate terminal 322 may be connected to an external driver (not shown) through a flexible printed board (not shown) and receive a scan signal output from the driver.

As shown in FIGS. 4A and 4B, the gate line 321 is formed on a transparent substrate 10. The insulation layers 35 and 38 are laminated on the gate line 321. The gate terminal 322 is electrically connected to the gate line 321 in contact holes 39d and 39e that are formed in the insulation layers 35 and 38. The portions where the gate line 321 and the gate terminal 322 are electrically connected are referred to as connections c1 and c2. The gate terminal 322 is deposited at the same time as the pixel electrode 20. The gate terminal 322 may be formed of a material which contains at least one kind of metal selected from indium oxide, tin oxide, and zinc oxide, just like the pixel electrode 20. As shown in FIG. 4B, a flat part of the gate terminal 322 which is formed on the insulation layer 38 serves as a pad that is actually connected to a flexible printed board (not shown).

The gate line 321 as a conductive structure has a laminated structure composed of the upper layer 321b and the lower layer 321a. This structure is detailed later.

As shown in FIGS. 2, 3A, 3B, 4A and 4B, the gate electrode 32, the source electrode 33, the drain electrode 34, the gate line 321, the source line 331, and the capacitor electrode 40 as the conductive structure has the laminated structure of the lower layers 32a, 33a, 34a, 321a, 331a and 40a and the upper layers 32b, 33b, 34b, 321b, 331b and 40b, respectively.

The lower layers 32a, 33a, 34a, 321a, 331a and 40a are formed of an aluminum alloy which contains at least one kind of Group 8 elements in the periodic table such as nickel (Ni) . As shown in FIGS. 2, 3A, 3B, 4A and 4B, the upper layers 32b, 33b, 34b, 321b, 331b and 40b are laminated on the lower layers 32a, 33a, 34a, 321a, 331a and 40a, respectively, and formed of an aluminum alloy which contains at least one kind of Group 8 elements in the periodic table such as nickel (Ni) and nitrogen. The upper layers 32b, 33b, 34b, 321b, 331b and 40b is made by adding nitrogen to an aluminum alloy which contains at least one kind of Group 8 elements in the periodic table such as nickel (Ni).

Laminating the upper layers 32b, 33b, 34b, 321b, 331b and 40b that are formed of an aluminum alloy which contains at least one kind of Group 8 elements in the periodic table such as nickel (Ni) and nitrogen respectively on the lower layers 32a, 33a, 34a, 321a, 331a and 40a that are formed of an aluminum alloy which contains at least one kind of Group 8 elements in the periodic table such as nickel (Ni) enables the formation of a conductive structure having high alkali resistance and high processing accuracy with a simple structure.

Further, this structure suppresses the occurrence of a void, which can occur at an edge of a line or electrode when heating the line or electrode that is formed of an aluminum alloy containing at least one kind of Group 8 elements. Because the upper layers 32b, 33b, 34b, 321b, 331b and 40b that are formed of an aluminum alloy which contains at least one kind of Group 8 elements in the periodic table such as nickel (Ni) and nitrogen are respectively placed on the lower layers 32a, 33a, 34a, 321a, 331a and 40a that are formed of an aluminum alloy which contains at least one kind of Group 8 in the periodic table, it is possible to reduce the stress of the insulations layers 35 and 38 above the laminated structures 32, 33, 34, 321, 331 and 40 from affecting the lower layers 32a, 33a, 34a, 321a, 331a and 40a, thereby suppressing the occurrence of a void in the laminated structures of the upper layers and the lower layers.

Preferably, the thickness of the upper layers 32b, 33b, 34b, 321b, 331b and 40b is between about 2 nm and about 50 nm.

This is because if the upper layers 32b, 33b, 34b, 321b, 331b and 40b have a thickness of less than about 2 nm, they cannot be deposited uniformly on the transparent substrate 10. Further, they cannot effectively prevent a void from occurring in the lower layers 32a, 33a, 34a, 321a, 331a and 40a when forming the insulation layers 35 and 38 above the laminated structures 32, 33, 34, 321, 331 and 40 during a manufacturing process. Further, if the upper layers 32b, 33b, 34b, 321b, 331b and 40b have a thickness of less than about 2 nm, the resistance to an organic alkaline solution that is used for patterning by photolithography decreases, causing the lower layers 32a, 33a, 34a, 321a, 331a and 40a to be dissolved in the organic alkaline solution and thus failing to form the line or electrode as a conductive structure on the transparent electrode 10 in uniform processing accuracy.

Normally, an etching rate of the aluminum alloy which contains at least one kind of Group 8 elements in the periodic table that is used for the lower layers 32a, 33a, 34a, 321a, 331a and 40a is higher than the aluminum alloy which contains at least one kind of Group 8 elements in the periodic table such as nickel (Ni) and nitrogen that is used for the upper layers 32b, 33b, 34b, 321b, 331b and 40b. Therefore, if the thickness of the upper layers 32b, 33b, 34b, 321b, 331b and 40b is larger than about 50 nm, the cross sectional shape of the lines or electrodes having the laminated structure of the upper layers and the lower layers is distorted, which deteriorates the coating characteristics of the insulation layers 35 and 38 formed above the upper layers to result in yield reductions.

As described above, it is preferred that the thickness of the upper layers 32b, 33b, 34b, 321b, 331b and 40b is between about 2 nm and about 50 nm. This enables the formation of a conductive structure having high alkali resistance and high processing accuracy with a simple structure.

If the laminated structure of the upper layers 32b, 33b, 34b, 321b, 331b and 40b and the lower layers 32a, 33a, 34a, 321a, 331a and 40a are directly connected to the pixel electrode 20, the source terminal 332, and the gate terminal 322 as transparent conductive layers, it is possible to form the pixel electrode 20, the source terminal 332, and the gate terminal 322 using a material containing at least one of indium oxide, tin oxide, and zinc oxide. In such a case, because the lower layers 32a and so on are formed of an aluminum alloy which contains at least one kind of Group 8 elements and the upper layers 32b and so on are formed of aluminum alloy which contains at least one kind of Group 8 elements and nitrogen, it is possible to avoid an oxide layer from being formed between the laminated structures and the pixel electrode 20, the source terminal 332, and the gate terminal 322 without interposing high melting point metal such as Chromium (Cr) between the laminated structures of the upper layers 32b etc. and the lower layers 32a etc. and the pixel electrode 20, the source terminal 332, and the gate terminal 322. In this way, it is possible to directly contact the aluminum alloy used for the electrodes and lines 32, 33, 34, 321, 331 and 40 and the metal of at least one of indium oxide, tin oxide, and zinc oxide to thereby establish electrical connection.

It is preferred that the thickness of the upper layers 32b etc. in the connections a, b1, c1 and c2 between the laminated structures of the upper layers 32b etc. and the lower layers 32a etc. and the pixel electrode 20, the source terminal 332, and the gate terminal 322 is smaller than the thickness of the upper layers 32b etc. in the area outside of the connections a, b1, c1 and c2. Specifically, the thickness of the upper layers 32b etc. inside the contact holes 39a, 39b, 39c, 39d and 39e is preferably smaller than the thickness of the upper layers 32b etc. outside the contact holes 39a etc. This reduces connection resistance in the connections a, b1, c1 and c2. Further, the upper layers 32b etc. inside the contact holes 39a etc. may be removed. This further reduces connection resistance in the connections a, b1, c1 and c2.

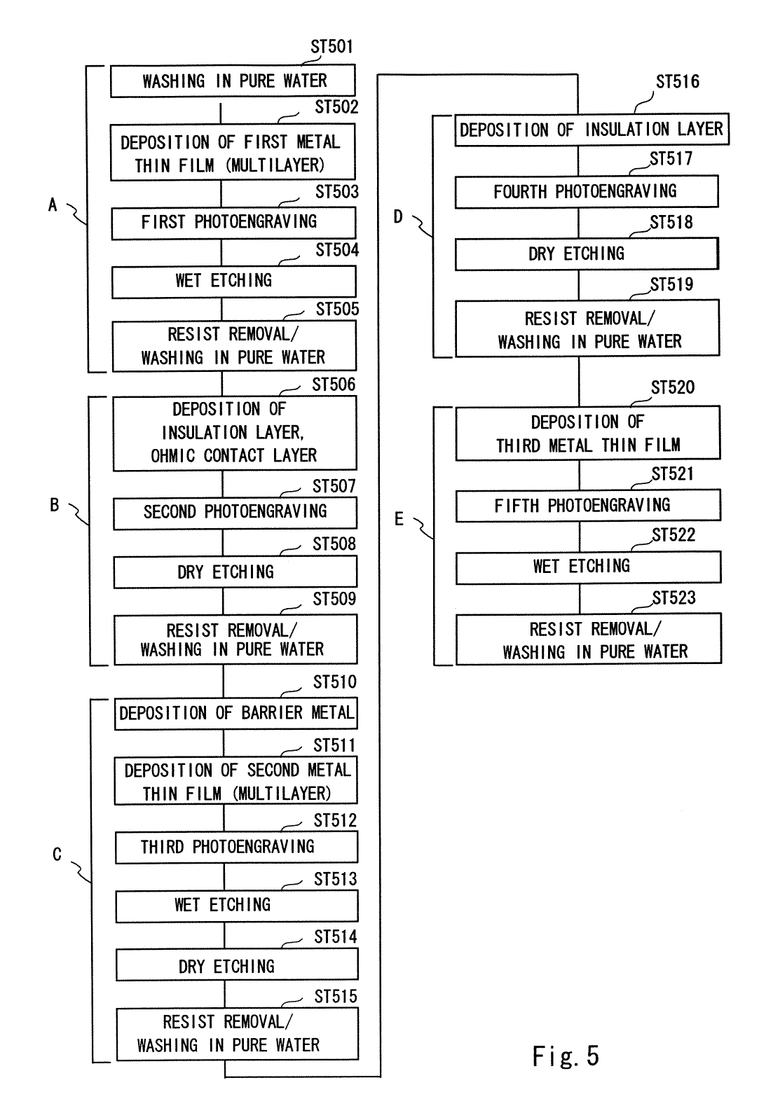

A method of manufacturing a TFT array substrate according to an exemplary embodiment of the invention is described hereinafter with reference to FIG. 5. FIG. 5 shows a manufacturing flow of a TFT array substrate of the first embodiment. For the convenience of description, the flow is divided into five processes of a process A to a process E as shown in FIG. 5.

The process A is described first. In the process A, the gate electrode 32, the gate line 321 and the capacitor electrode 40 are formed above the transparent substrate 10.

Specifically, the transparent substrate 10 that is formed of light-transmissive glass, polycarbonate, acrylic resin or the like is washed using pure water or hot sulfuric acid in Step(abbreviated herein as ST) 501.

Then, a first metal thin film is deposited (ST502) . More specifically, a lower layer of an aluminum alloy containing at least one kind of Group 8 elements in the periodic table is deposited on the transparent substrate 10 and further an upper layer of an aluminum alloy containing at least one kind of Group 8 elements in the periodic table such as nickel and nitrogen is deposited on the lower layer (ST502) In a preferred example, by sputtering using argon (Ar) gas, a lower layer of AlNiNd is formed to a thickness of 200 nm, using an aluminum alloy of AlNiNd which contains nickel (Ni) that is a Group 8 elements in the periodic table as a target. This sputtering uses a DC magnetron sputtering system with a deposition power density of 3W/cm² and an Ar gas flow rate of 40 sccm (=6.76*10−²Pa·m³/s).

Further, by reactive sputtering using a mixed gas of Ar gas and nitrogen (N₂) gas, an upper layer of AlNiNdN that adds N to AlNiNd is formed to a thickness of 10 nm, using an aluminum alloy of AlNiNd which contains nickel (Ni) that is a Group 8 elements in the periodic table as a target.

This sputtering uses a DC magnetron sputtering system with a deposition power density of 3W/cm², an Ar gas flow rate of 40 sccm (=6.76*10−²Pa·m³/s), and an N₂ gas flow rate of 20 sccm (=3.38*10−²Pa·m³/s). Inthisway, it is possible to form the lower layer and the upper layer easily simply by changing a part of sputtering conditions without making any change to manufacturing facilities. Because the target for forming the upper layer of AlNiNdN is the same as the target for forming the lower layer of AlNiNd, the upper layer of AlNiNdN and the lower layer of AlNiNd can be formed in the same deposition chamber simply by changing a sputtering gas. It is thereby possible to sequentially form the lower layer and the upper layer efficiently.

Alternatively, an upper layer of AlNiNdN may be formed by sputtering using Ar gas, using an aluminum alloy of AlNiNdN as a target. Further, an aluminum alloy which contains at least one kind of Group 8 elements in the periodic table may be used as a target. This enables easy formation of the lower layer and the upper layer simply by changing the target. This process eliminates the need for performing reactive sputtering, which is fundamentally unstable. This process is thereby as stable as the process of depositing Cr, Mo or the like in the lower layer of the Al alloy. Thus, this method simplifies the deposition process compared with the technique disclosed in the patent document 1 and achieves a stable process with a low defect rate. An amount to add at least one Group 8 element is preferably between 1at % to 5at %. This enables easy formation of a conductive structure having high alkali resistance and high processing accuracy with a simple structure while maintaining the original characteristics of aluminum such as low resistance and high reflectance.

In this manner, the lower layer of AlNiNd having a thickness of 200 nm is formed on the transparent substrate 100, and the upper layer of AlNiNdN having a thickness of 10 nm is formed on the lower layer, so that the laminated structure of the lower layer of AlNiNd and the upper layer of AlNiNdN is formed on the transparent substrate 10. The nitrogen elemental composition of the AlNiNdN upper layer is about 18 weight percent (%). In ST 502, if the upper layer of AlNiNdN and the lower layer of AlNiNd are maintained in a vacuum pumping system without being exposed to atmosphere, it is possible to suppress the formation of an interface oxide layer that has an adverse affect on conductivity and improve the productivity.

Then, the first photoengraving is performed (ST503). In this step, photoresist as a photosensitive material is coated on the upper layer of AlNiNdN and then baked. After the baking, a mask having a prescribed pattern is placed and the photoresist is exposed through the mask for patterning. Then, the photoresist is developed using an organic alkaline developer, for example, and thereby dissolved. Because the upper layer is formed of an aluminum alloy containing at least one kind of Group 8 elements in the periodic table and nitrogen such as AlNiNdN which has higher alkali resistance than the aluminum alloy containing at least one kind of Group 8 elements in the periodic table such as AlNiNd that forms the lower layer, it is possible to prevent the laminated structure of the upper layer and the lower layer from being dissolved in the organic alkaline developer during development.

Then, wet etching is performed (ST504). In this step, the laminated structure of the lower layer of AlNiNd and the upper layer of AlNiNdN in the area where photoresist is not formed is etched simultaneously using a mixed solution of phosphoric acid and nitric acid, for example. The laminated structure of the lower layer of AlNiNd and the upper layer of AlNiNdN is thereby patterned into a desired shape. This eliminates the need for performing etching in two times which is required when using Cr, Mo and so on in the lower layer of an Al alloy, thereby simplifying a deposition process compared with the technique disclosed in the patent document 1. The “simultaneously” not only indicates performing etching of the upper layer and the lower layer exactly at the same time but also indicates performing etching of the upper layer of AlNiNdN and etching of the lower layer of AlNiNd successively without interruption. The upper layer of AlNiNdN and the lower layer of AlNiNd may be etched separately.

After that, the photoresist on the transparent substrate 10 is removed (ST505), and the transparent substrate 10 after removing the photoresist is washed in pure water (ST505).

The process A thereby forms the gate electrode 32, the gate line 321 and the capacitor electrode 40 above the transparent substrate.

The process B is described hereinafter. In the process B, the semiconductor layer 31, the insulation layer 35 and the ohmic contact layer 36 are formed above the transparent substrate 10.

Firstly, a silicon nitride (SiN) layer that is a material of the insulation layer 35 is deposited on the transparent substrate 10, and an amorphous silicon layer that is a material of the semiconductor layer 31 is deposited on the silicon nitride layer. Further, an n+ amorphous silicon layer that is a material of the ohmic contact layer 36 is deposited on the amorphous silicon layer (ST506) . Specifically, the silicon nitride (SiN) layer of 400 nm in thickness, the amorphous silicon layer of 150 nm in thickness, and the n+amorphous silicon layer of 30 nm in thickness are sequentially deposited using chemical vapor deposition (CVD) process. Phosphorus (P) is added as impurity to the n+amorphous silicon layer.

Then, the second photoengraving is performed (ST507) by the same processing as in ST 503. After that, dry etching is performed (ST508) . The dry etching process may use fluorine (F) gas and etch the n+amorphous silicon layer, the amorphous silicon layer, and the silicon nitride (SiN) layer into a desired pattern.

Further, the photoresist on the transparent substrate 10 is removed (ST509), and the transparent substrate 10 after removing the photoresist is washed in pure water (ST509).

The process B thereby forms the semiconductor layer 31, the insulation layer 35 and the ohmic contact layer 36 above the transparent substrate 10.

The process C is described hereinafter. In the process C, the barrier metal 37, the source electrode 33, the source line 331 and the drain electrode 34 are formed above the transparent substrate 10.

Firstly, a barrier metal layer is deposited above the transparent substrate 10 (ST510) . Preferably, the barrier metal layer to serve as the barrier metal 37 is formed of a high melting point metal of molybdenum (Mo), chromium (Cr), titanium (Ti), tantalum (Ta), tungsten (W) or an alloy mainly composed of these metals by sputtering using argon (Ar) gas. The Mo, Cr, Ti, Ta, W or an alloy mainly composed of them have suitable contact characteristics with the ohmic contact layer 36 that is formed of n+amorphous silicon, for example. In this example, the barrier metal layer of 50 nm in thickness is formed of Mo that is a high melting point metal by the sputtering process using Ar gas.

Further, a second metal thin film (multilayer) is deposited (ST511) by the same processing as in ST 502.

In this way, the Mo barrier metal layer having a thickness of 50 nm, the lower layer of AlNiNd having a thickness of 200 nm, and the upper layer of AlNiNdN having a thickness of 10 nm laminated on the lower layer are formed above the insulation layer 35, the semiconductor layer 31 and so on above the transparent substrate 100. The laminated structure of the lower layer of AlNiNd and the upper layer of AlNiNdN are thus formed above the transparent substrate 100. The nitrogen elemental composition of the AlNiNdN upper layer is still about 18 weight percent (%).

Then, the third photoengraving is performed (ST512) by the same processing as in ST 503. After that, wet etching is performed (ST513) by the same processing as in ST 504. The Mo barrier metal layer and the laminated structure of the AlNiNd lower layer and the AlNiNdN upper layer are thereby etched into a desired pattern.

Further, dry etching is performed (ST514) . The dry etching process may use fluorine (F) gas and etch the n+ amorphous silicon layer to serve as the ohmic contact layer 36 into a desired pattern. Then, the photoresist on the transparent substrate 10 is removed (ST515), and the transparent substrate 10 after removing the photoresist is washed in pure water (ST515).

The process C thereby forms the barrier metal 37, the source electrode 33, the source line 331 and the drain electrode 34 above the transparent substrate 10.

The process D is described hereinafter. In the process D, the insulation layer 38 is formed on the transparent substrate 10.

Firstly, a silicon nitride (SiN) layer that is a material of the insulation layer 38 is deposited above the transparent substrate 10 (ST516) . In a preferred example, a silicon nitride (SiN) layer of 300 nm in thickness may be formed by the chemical vapor deposition (CVD) process.

Then, the fourth photoengraving is performed (ST517) by the same processing as in ST 503.

After that, dry etching is performed (ST518). The dry etching process may use fluorine (F) gas and etch the SiN layer into a desired pattern. During the processing of ST518, the contact holes 39a, 39b, 39c, 39d and 39e may be created in the insulation layer 38. In order to create the contact holes 39d and 39e, it is necessary to etch both of the insulation layers 35 and 38. Alternatively, it is possible to create the contact holes 39d and 39e in the insulation layers 35 prior to starting the process D and then create the contact holes 39d and 39e in the insulation layers 38 by the ST 518.

Further, during the processing of S518, a part or all of the upper layers 34b, 321b and 331b in the contact holes 39a, 39b, 39c, 39d and 39e may be removed. In such a case, the thickness of the upper layers 34b etc. inside the contact holes 39a etc. is smaller than the thickness of the upper layers 34b etc. outside the contact holes 39a etc. As a result, the laminated structure of the upper layers 34b etc. and the lower layers 34a etc. and the pixel electrode 20, the gate terminal 322 and the source terminal 332 may be electrically connected with lower resistance inside the connections a, b1, c1 and c2.

After that, the photoresist on the transparent substrate 10 is removed (ST519), and the transparent substrate 10 after removing the photoresist is washed in pure water (ST519).

The process E is described hereinafter. In the process E, the pixel electrode 20, the gate terminal 322 and the source terminal 332 are formed above the transparent substrate 10.

Firstly, a third metal thin film is deposited (ST520). Specifically, a transparent conductive layer that is a material of the pixel electrode 20, the gate terminal 322 and the source terminal 332 are deposited above the transparent substrate 10. In a preferred example, an ITO film that is a mixture of indium oxide (In₂O₃) and tin oxide (SnO₂) is formed to a thickness of 100 nm by sputtering using argon (Ar) gas. At this time, the ITO film is deposited also inside the contact holes 39a, 39b, 39c, 39d and 39e that are created in ST518, and thereby the ITO film and the laminated structure of the upper layers 34b etc. and the lower layer 34a etc. are electrically connected.

Then, the fifth photoengraving is performed (ST521) by the same processing as in ST 503. After that, wet etching is performed (ST522) by the same processing as in ST 504, thereby forming the ITO film into a desired pattern shape.

Then, the photoresist on the transparent substrate 10 is removed (ST523), and the transparent substrate 10 after removing the photoresist is washed in pure water (ST523).

The process E thereby forms the pixel electrode 20, the gate terminal 322 and the source terminal 332 above the transparent substrate 10. The TFT array substrate 100 is thereby produced.

Laminating the upper layers 32b etc. that are formed of an aluminum alloy which contains at least one kind of Group 8 elements in the periodic table and nitrogen respectively on the lower layers 32a etc. that are formed of an aluminum alloy which contains at least one kind of Group 8 elements in the periodic table enables the formation of a conductive structure having high alkali resistance and high processing accuracy with a simple structure. Further, even if an organic alkaline solution is used for removing the photoresist, this structure prevents the laminated structure of the upper layer 32b and the lower layer 32a from being dissolved.

Though the ITO film is used as a transparent conductive layer for forming the pixel electrode 20, the gate terminal 322 and the source terminal 332, it is possible to use a transparent conductive layer that contains at least one of indium oxide, tin oxide, and zinc oxide. For example, if IZO (Indium Zing Oxide) film which is the mixture of indium oxide and zinc oxide is used, an etchant that is used for ST522 may be a mild acidic solution such as oxalic acid. Thus, the use of the IZO film as a transparent conductive layer enables the use of a mild acidic solution. As a result, even if an aluminum alloy with low acid resistance is used for the laminated structure of the upper layer 32b etc. and the lower layer 32a etc., it is possible to prevent the laminated structure of the upper layer 32b etc. and the lower layer 32a etc. from being disconnected or corroded due to permeation of a drug solution.

If the oxygen composition of the sputtering film of each of indium oxide, tin oxide, and zinc oxide is smaller than chemical theoretical composition, and the characteristics such as transmittance and specific resistance are not good, it is preferred to use a mixed gas of an oxygen gas and H₂O gas in addition to the Ar gas as sputtering gas to deposit the layer. Further, if thermal treatment at about 230° C. is performed thereon, an amorphous transparent conductive film that is etchable by oxalic acid is crystallized, thereby enabling an increase in the transmittance of the transparent conductive layer to form the pixel electrode 20, reduction in specific resistance, and improvement in resistance to a drug solution.

### Second Embodiment

The structure of the TFT array substrate according to a second exemplary embodiment of the present invention is described hereinafter with reference to the drawings.

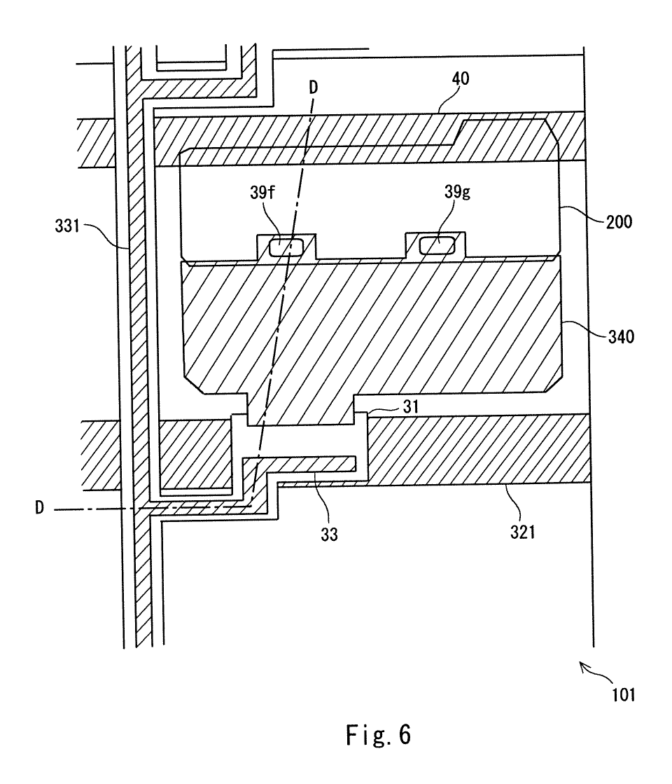

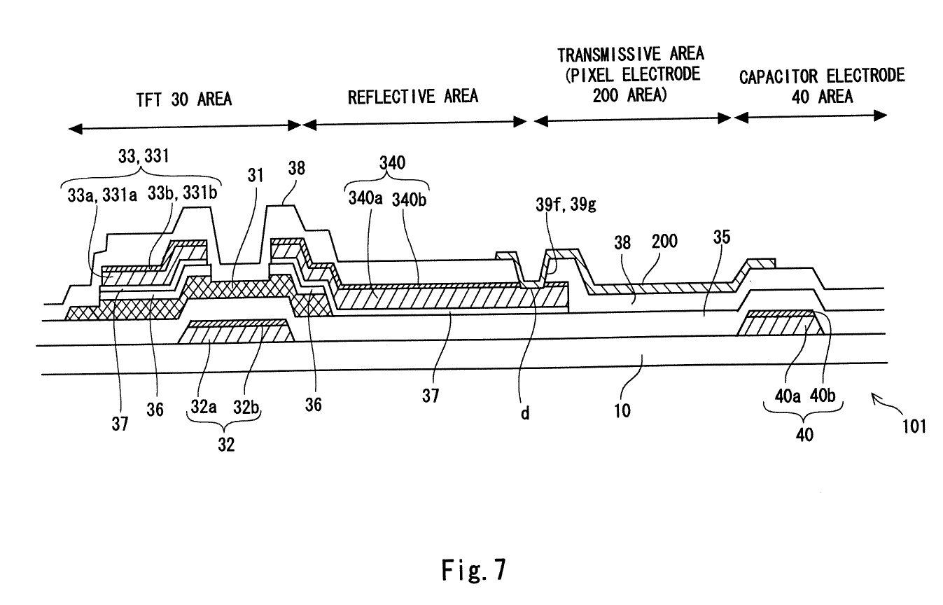

FIG. 6 is a plan view to describe the structure of main parts of the TFT array substrate according to the second embodiment. FIG. 7 is a sectional view along line D-D in FIG. 6 to describe the structure of main parts of the TFT array substrate according to the second embodiment.

Though the first embodiment describes the TFT array substrate 100 that is used for a transmissive TFT liquid crystal display, the second embodiment describes a TFT array substrate 101 that is used for a transflective liquid crystal display.

In the TFT array substrate 100 of the first embodiment, a pixel has only the transmissive area which corresponds to the pixel electrode 20 area in FIG. 1 and not has a reflective area as shown in FIGS. 1 and 2. On the other hand, in the TFT array substrate 101 of the second embodiment, a pixel has both a reflective area and a transmissive area as shown in FIGS. 6 and 7.

As shown in FIGS. 6 and 7, a pixel includes a reflective area and a transmissive area. The reflective area has a drain electrode 340, and the transmissive area has a pixel electrode 200. The drain electrode 340 and the pixel electrode 200 both have a rectangular shape.

As shown in FIG. 7, in the reflective area, the drain electrode 340 is formed on the lamination of the barrier metal 37 and the insulation layer 35 that are formed above the transparent substrate 10. The insulation layer 38 is formed on the drain electrode 340.

As shown in FIGS. 6 and 7, the pixel electrode 200 is formed above the part of the drain electrode 340 which is close to the pixel electrode 200 area with the insulation layer 38 interposed therebetween. The pixel electrode 200 is electrically connected to the drain electrode 340 in contact holes 39f and 39g that are created in the insulation layer 38. Thus, the pixel electrode 200 is connected to the TFT 30 through the drain electrode 340. The portion where the pixel electrode 200 and the drain electrode 340 are electrically connected is referred to as a connection d.

The pixel electrode 200 is formed of a transparent conductive layer just like in the first embodiment. A material of the pixel electrode 200 may be a metal that contains at least one of indium oxide, tin oxide, and zinc oxide.

The drain electrode 340 as the conductive structure is formed of a laminated structure of an upper layer 340b and a lower layer 340a. The lower layer 340a is formed of an aluminum alloy which contains at least one kind of Group 8 elements in the periodic table such as nickel (Ni), and the upper layer 340b is formed of an aluminum alloy which contains at least one kind of Group 8 elements in the periodic table such as nickel (Ni) and nitrogen.

Because the drain electrode 340 having the laminated structure of the upper layer 340b and the lower layer 340a in the reflective area, this embodiment does not only have the effects described in the first embodiment but also enables the use of the drain electrode 340 as a reflective layer, thereby eliminating the need for forming another reflective layer in the reflective area.

The connection d has the same structure as the connections a, b1, b2, c1 and c2 in the first embodiment.

The comparison between the reflectance of the conductive structure of this embodiment and the reflectance of a metal film that is typically used for an electrode or line is as follows.

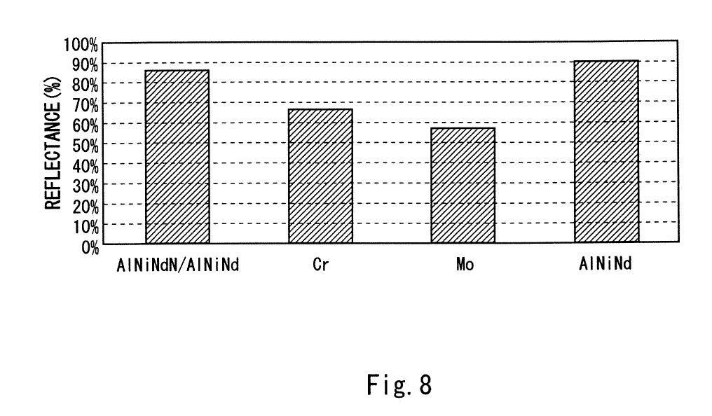

FIG. 8 is a graph showing the reflectance of the conductive structure of this embodiment and the reflectance of a metal film that is typically used for an electrode or line.

As the conductive structure of this embodiment, the laminated structure of aluminum alloys composed of the lower layer of AlNiNd having a thickness of about 200 nm and the upper layer of AlNiNdN having a thickness of about 10 nm is used. As comparative structures, metal thin films of Cr, Mo and AlNiNd each having the same thickness are prepared. The reflectance of these materials for incident light with a wavelength of 550 nm is measured.

As a result, the reflectance of the laminated structure of AlNiNdN and AlNiNd is higher than the reflectance of the Cr film and the Mo film and lower than the reflectance of the AlNiNd film as shown in FIG. 8. The reflectance of the AlNiNd film is about 90%, and the reflectance of the laminated structure of AlNiNdN and AlNiNd is about 87%. The laminated structure of AlNiNdN and AlNiNd which is the conductive structure of this embodiment has the same level of reflectance as the AlNiNd film and thus can be used as a reflective layer used in the reflective area of the transflective liquid crystal display.

### Third Embodiment

The structure of the TFT array substrate according to a third exemplary embodiment of the present invention is described hereinafter with reference to the drawings.

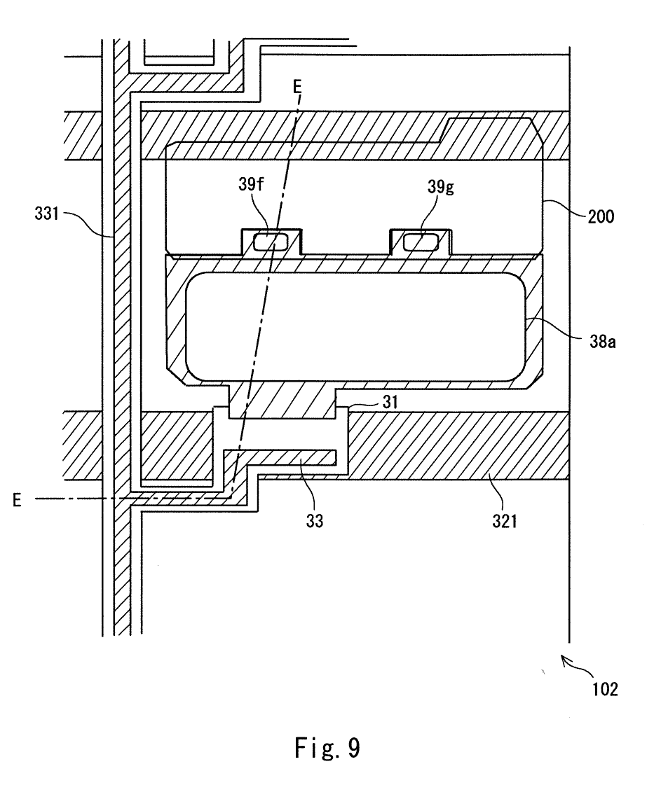

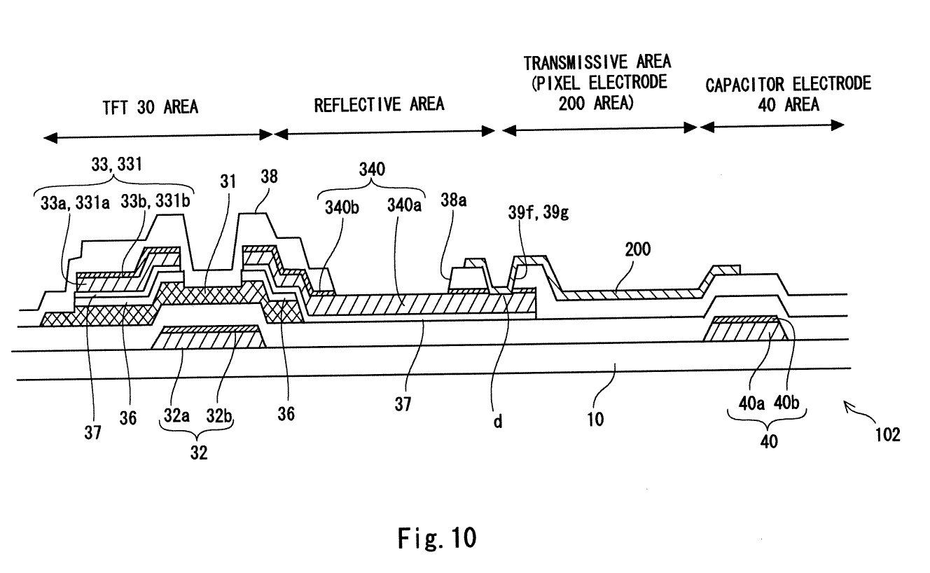

FIG. 9 is a plan view to describe the structure of main parts of the TFT array substrate according to the third embodiment. FIG. 10 is a sectional view along line E-E in FIG. 9 to describe the structure of main parts of the TFT array substrate according to the third embodiment.

The third embodiment describes a TFT array substrate 102 that is used for a transflective liquid crystal display as in the second embodiment.

Though the insulation layer 38 is laminated on the drain electrode 340 in the reflective area of a pixel in the TFT array substrate 101 of the second embodiment as shown in FIGS. 6 and 7, the drain electrode 340 in the reflective area of a pixel is exposed in the TFT array substrate 102 of this embodiment as shown in FIGS. 9 and 10.

As shown in FIGS. 9 and 10, an opening 38a exists in the insulation layer 38. The position of the opening 38a corresponds to the reflective area in a pixel. The drain electrode 340 is exposed inside the opening 38a.

In order to create the opening 38a in the insulation layer 38, a mask having a pattern for creating the opening 38a may be used in the photoengraving performed in the step ST517 in the process D shown in FIG. 5. Specifically, a mask having a pattern for creating the opening 38a at the same time as creating the contact holes 39b, 39c, 39d, 39e, 39f and 39g may be used. This eliminates the need for additional deposition and pattering process.

As described in the foregoing, because the drain electrode 340 is exposed in the reflective area in the pixel, the light incident on the drain electrode 340 can be reflected effectively.

The upper layer 340b inside the opening 38a may be removed during the processing in ST 510 shown in FIG. 5. The lower layer 340a is thereby exposed inside the opening 38a. If the lower layer 340a is formed of a material having higher reflectance than a material of the upper layer 340b, higher reflectance can be obtained. For example, this is the case when using AlNiNdN for the upper layer 340b and AlNiNd for the lower layer 340a as shown in FIG. 8.

### Fourth Embodiment

The structure of the TFT array substrate according to a fourth exemplary embodiment of the present invention is described hereinafter with reference to the drawings.

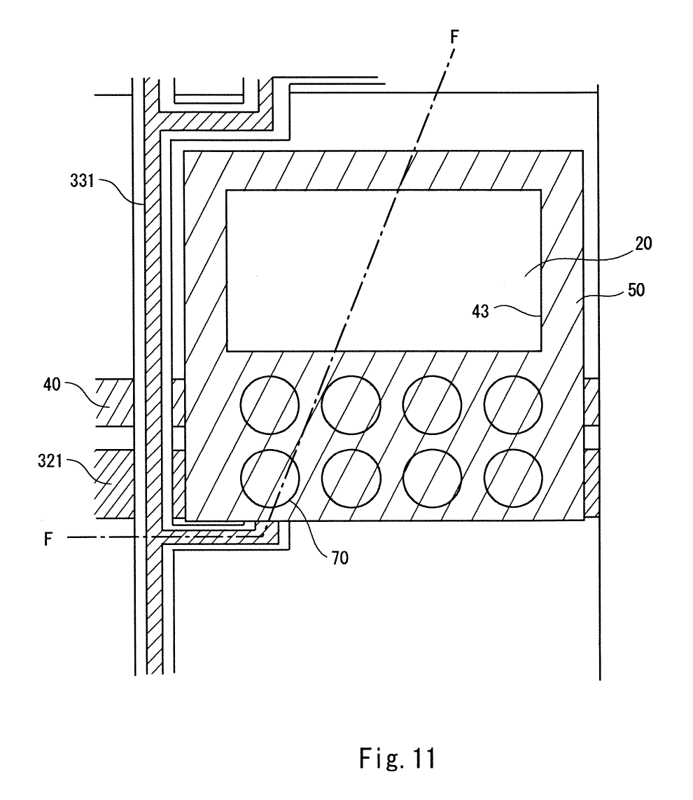

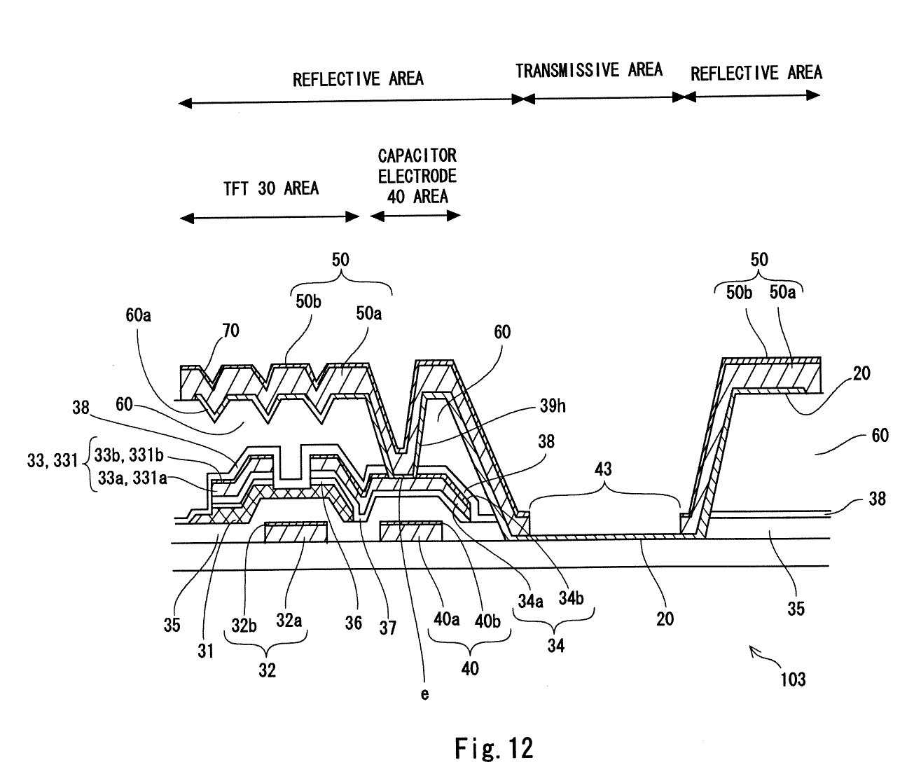

FIG. 11 is a plan view to describe the structure of main parts of the TFT array substrate according to the fourth embodiment. FIG. 12 is a sectional view along line F-F in FIG. 11 to describe the structure of main parts of the TFT array substrate according to the fourth embodiment.

The fourth embodiment describes a TFT array substrate 103 that is used for a transflective liquid crystal display as in the second and third embodiments.

In the TFT array substrates 101 and 102 according to the second and third embodiments, the drain electrode 340 is placed in the reflective area in a pixel and serves as a reflective layer as shown in FIGS. 6, 7, 8 and 9. On the other hand, in the TFT array substrate 103 according to the fourth embodiment, in addition to the drain electrode 34, a reflective layer 50 is formed above the TFT 30 in the reflective area in a pixel as shown in FIGS. 11 and 12. Further, in the TFT array substrates 101 and 102 of the second and third embodiments, the capacitor electrode 40 is placed separately from the gate line 321 as shown in FIGS. 6, 7, 8 and 9. On the other hand, in the TFT array substrate 103 according to the fourth embodiment, the capacitor electrode 40 is placed adjacent to the gate line 321 as shown in FIGS. 11 and 12.

As shown in FIGS. 11 and 12, the insulation layer 38 is laminated on the source electrode 33 and the drain electrode 34 that constitute the TFT 30 and the capacitor electrode 40. Further, an insulative resin layer 60 is laminated on the insulation layer 38. The pixel electrode 20 as a conductive structure is formed above the resin layer 60. A reflective layer 50 as a conductive structure is laminated on the pixel electrode 50 in close contact therewith.

Further, a plurality of depressions 70 are created on the reflective film 50 as shown in FIGS. 11 and 12. The depressions 70 are formed to control scattered light of reflected light. Though one depression 70 exists on the line F-F in FIG. 11, FIG. 12 illustrates a plurality of depressions 70 for convenience of description.

As shown in FIG. 12, the resin layer 60 and the insulation layer 38 have a contact hole 39h. Inside the contact hole 39h, the pixel electrode 20 is connected to the drain electrode 34. The portion where the pixel electrode 20 and the drain electrode 34 are electrically connected is referred to as a connection e.

Because the reflective layer 50 is laminated on the pixel electrode 20 as shown in FIG. 12, the reflective layer 50 is electrically connected to the drain electrode 34 through the pixel electrode 20. Thus, the reflective layer 50 also serves as an electrode.

Further, as shown in FIG. 12, the pixel electrode 20 is formed on the transparent substrate 10 in the transmissive area in a pixel. In the transmissive area, the reflective layer 50 has an opening 43 so that the pixel electrode 20 is exposed.

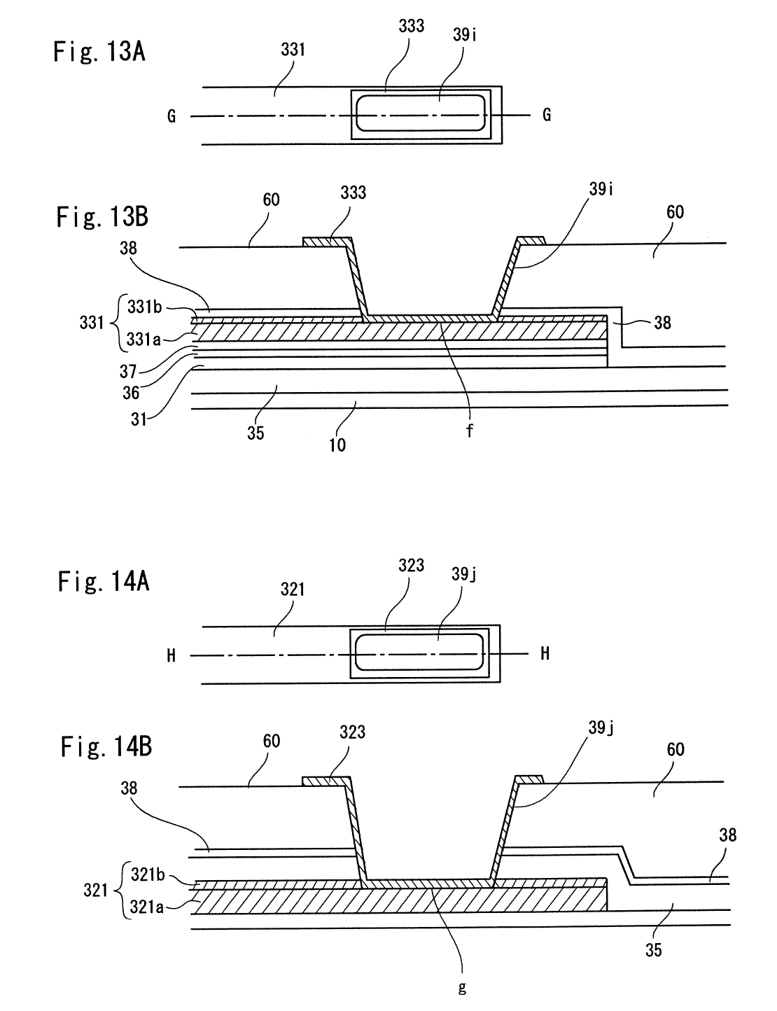

The structure of a source terminal 333 at an end of the source line 331 is described hereinafter with reference to FIGS. 13A and 13B. FIGS. 13A and 13B show a connection of the source line and the source terminal. FIG. 13A is a plan view, and the FIG. 13B is a sectional view along line G-G of FIG. 13A.

In the first embodiment, the source terminal 332 and the source line 331 are electrically connected inside the two small contact holes 39b and 39c as shown in FIGS. 3A and 3B. On the other hand, in the fourth embodiment, the source terminal 333 and the source line 331 are electrically connected inside one large contact hole 39i as shown in FIGS. 13A and 13B. The portion where the source line 331 and the source terminal 333 are electrically connected is referred to as a connection f.

Further, in the first embodiment, the contact holes 39b and 39c for electrically connecting the source terminal 332 and the source line 331 are created only in the insulation layer 38 as shown in FIGS. 3A and 3B. On the other hand, in the fourth embodiment, the contact hole 39i for electrically connecting the source terminal 333 and the source line 331 is created in the insulation layer 38 and the resin layer 60 as shown in FIGS. 13A and 13B.

Furthermore, in the first embodiment, the flat part of the source terminal 332 which is placed on the insulation layer 38 serves as a pad that is actually connected to a flexible printed board as shown in FIGS. 3A and 3B. On the other hand, in the fourth embodiment, the flat part placed inside the contact hole 39i serves as a pad that is actually connected to a flexible printed board as shown in FIGS. 13A and 13B.

In the fourth embodiment, the electrical connection between the source line 331 and the source terminal 332 may be established by the structure as shown in FIGS. 3A and 3B.

The structure of a gate terminal 323 at an end of the gate line 321 is described hereinafter with reference to FIGS. 14A and 14B. FIGS. 14A and 14B show a connection of the gate line and the gate terminal. FIG. 14A is a plan view, and the FIG. 14B is a sectional view along line H-H of FIG. 14A.

In the first embodiment, the gate terminal 322 and the gate line 321 are electrically connected inside the two small contact holes 39d and 39e as shown in FIGS. 4A and 4B. On the other hand, in the fourth embodiment, the gate terminal 321 and the gate line 323 are electrically connected inside one large contact hole 39j as shown in FIGS. 14A and 14B. The portion where the gate line 321 and the gate terminal 322 are electrically connected is referred to as a connection g.

Further, in the first embodiment, the contact holes 39d and 39e for electrically connecting the gate terminal 322 and the gate line 321 are created only in the insulation layers 35 and 38 as shown in FIGS. 4A and 4B. On the other hand, in the fourth embodiment, the contact hole 39j for electrically connecting the gate terminal 323 and the gate line 321 is created in the insulation layers 35 and 38 and the resin layer 60 as shown in FIGS. 14A and 14B.

Furthermore, in the first embodiment, the flat part of the gate terminal 332 which is placed on the insulation layer 38 serves as a pad that is actually connected to a flexible printed board as shown in FIGS. 4A and 4B. On the other hand, in the fourth embodiment, the flat part placed inside the contact hole 39j serves as a pad that is actually connected to a flexible printed board as shown in FIGS. 14A and 14B.

In the fourth embodiment, the electrical connection between the gate line and the gate terminal may be established by the structure as shown in FIGS. 4A and 4B.

As shown in FIGS. 12, 13b and 14b, the reflective layer 50 as the conductive structure has the laminated structure of the lower layer 50a and the upper layer 50b just like the gate electrode 32, the source electrode 33, the drain electrode 34, and gate line 323, the source line 333 and the capacitor electrode 40. The lower layer 50a is formed of an aluminum alloy which contains at least one kind of Group 8 elements in the periodic table such as nickel (Ni) . The upper layer 50b that is laminated on the lower layer 50a is formed by adding nitrogen to an aluminum alloy which contains at least one kind of Group 8 elements in the periodic table such as nickel (Ni).

In this way, laminating the upper layer 50b formed of an aluminum alloy which contains at least one kind of Group 8 elements in the periodic table and nitrogen on the lower layer 50a formed of an aluminum alloy which contains at least one kind of Group 8 elements in the periodic table enables the formation of a conductive structure having high alkali resistance and high processing accuracy with a simple structure, thus having the same effect as the first embodiment.

The thickness of the upper layer 50b in the connections e, f and g is preferably smaller than the thickness of the upper layer 50b in the area other than the connections e, f and g. This reduces connection resistance in the connections e, f and g. Further, the upper layer 50b in the connections e, f and g may be removed. This further reduces connection resistance in the in the connections e, f and g.

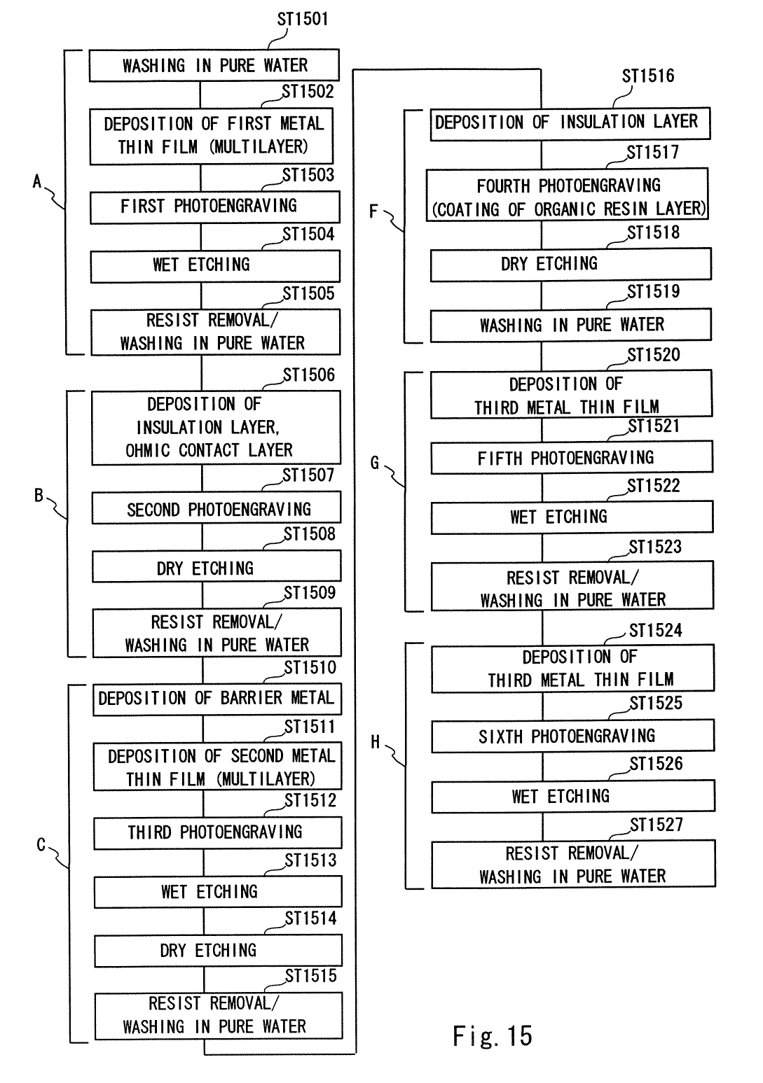

A method of manufacturing a TFT array substrate 103 according to the fourth embodiment of the invention is described hereinafter with reference to FIG. 15. FIG. 15 shows a manufacturing flow of a TFT array substrate of the fourth embodiment. For the convenience of description, the flow is divided into a plurality of processes as in FIG. 5.

As shown in FIG. 15, the processes A to C are the same as those in the manufacturing flow of the TFT array substrate according to the first embodiment. Therefore, the description of the processes A to C in the manufacturing method of the TFT array substrate 103 of the fourth embodiment is omitted. After completing the process C, the barrier metal 37, the source electrode 33, the source line 331, the gate electrode 32, the gate line 321 and the drain electrode 34 are formed above the transparent substrate 10.

The process F is described hereinafter. In the process F, the insulation layer 38 and the resin layer 60 are formed on the transparent substrate 10.

Firstly, a silicon nitride (SiN) layer that is a material of the insulation layer 38 is deposited above the transparent substrate 10 (ST1516) . In a preferred example, a silicon nitride (SiN) layer of 100 nm in thickness may be formed by the chemical vapor deposition (CVD) process.

Then, the fourth photoengraving is performed (ST1517).

Firstly, an organic resin film that is a material of the resin layer 60 is coated on the insulation layer 38 and then exposed and developed. At this time, a depression 60a is created in the organic resin film in the position corresponding to the depression 70. Then, the organic resin film is baked. The baking increases the shape sustainability of the resin layer 60 that is formed of the organic resin film. In a preferred example, an organic resin film PC-335 available from JSR Corporation is deposited to 3 um, a plurality of depressions 60a are created on the surface of the organic resin film, and the organic resin film having the depressions 60a is baked at about 150° C.

After that, dry etching is performed (ST1518). The dry etching process may use fluorine (F) gas and etch the SiN layer into a desired pattern. During the processing of ST1518, contact holes 39h, 39i and 39j may be created in the insulation layer 38, the resin layer 60 and so on. In order to create the contact hole 39j, it is necessary to etch the insulation layers 35, 38, and the resin layer 60. Alternatively, it is possible to create the contact hole 39j in the insulation layer 35 prior to starting the process F.

Further, during the processing of S1518, a part or all of the upper layers 34b, 321b and 331b in the contact holes 39h, 39i and 39j may be removed. In such a case, the thickness of the upper layers 34b etc. inside the contact holes 39hetc. is smaller than the thickness of the upper layers 34b etc. outside the contact holes 39h etc. As a result, the laminated structure of the upper layers 34b etc. and the lower layers 34a etc. and the pixel electrode 20, the gate terminal 323 and the source terminal 333 may be electrically connected inside the connections e, f and g with lower resistance.

After that, the transparent substrate 10 is washed in pure water (ST1519) . Because the organic film, not the photoresist, is coated in ST1517, there is no need to remove the photoresist from the transparent substrate 10 in ST1519. However, if the photoresist removal process is performed prior to the washing in pure water in ST1519, it is possible to remove a decayed contaminated foreign matter of the organic film which is partly generated during the dry etching in ST1518, thereby increasing yield.

The process G is described hereinafter. In the process G, the pixel electrode 20, the gate terminal 323 and the source terminal 333 are formed above the transparent substrate 10.

Firstly, a third metal thin film is deposited (ST1520) by the same process as in ST520. At this time, the ITO film is deposited also inside the contact holes 39h, 39i and 39j that are created in ST1518, and the ITO film and the laminated structure of the upper layers 34b etc. and the lower layers 34a etc. are electrically connected.

Then, the fifth photoengraving is performed (ST1521) by the same processing as in ST 521. After that, wet etching is performed (ST1522) by the same processing as in ST 522, thereby forming the ITO film into a desired pattern shape.

Then, the photoresist on the transparent substrate 10 is removed (ST1523), and the transparent substrate 10 after removing the photoresist is washed in pure water (ST1523).

The process thereby forms the pixel electrode 20, the gate terminal 323 and the source terminal 333 above the transparent substrate 10.

The process H is described hereinafter. In the process H, the reflective layer 50 is formed above the transparent substrate 10.

Firstly, a fourth metal thin film is deposited (ST1524) by the same process as in ST502.

The lower layer of AlNiNd having a thickness of 200 nm and the upper layer of AlNiNdN having a thickness of 10 nm which is formed on the lower layer are thereby formed on the resin layer 60 above the transparent substrate 100. The nitrogen elemental composition of the AlNiNdN upper layer is about 18 weight percent (%).

Then, the sixth photoengraving is performed (ST1525) by the same processing as in ST 503. After that, wet etching is performed (ST1526) by the same processing as in ST 504, thereby forming the laminated structure of the lower layer of AlNiNd and the upper layer of AlNiNdN into a desired pattern shape.

Then, the photoresist on the transparent substrate 10 is removed (ST1527), and the transparent substrate 10 after removing the photoresist is washed in pure water (ST1527).

The process thereby forms the reflective layer 50 above the transparent substrate 10. The TFT array substrate 103 is thereby produced.

In this way, laminating the upper layer 50b formed of an aluminum alloy which contains at least one kind of Group 8 elements in the periodic table and nitrogen on the lower layer 50a formed of an aluminum alloy which contains at least one kind of Group 8 elements in the periodic table enables the formation of a conductive structure having high alkali resistance and high processing accuracy with a simple structure. Further, even if an organic alkaline solution is used for removing the photoresist, this structure prevents the laminated structure of the upper layer 50b and the lower layer 50a from being dissolved.

It is further possible to perform light etching in a short time by wet etching using a solution containing phosphoric acid and nitric acid or dry etching using fluorine gas after the process H shown in FIG. 15, thereby removing the upper layer 50b of the reflective layer 50 to expose the lower layer 50a of the reflective layer 50. This further increases the reflective characteristics of the reflective layer 50.

Although the invention has been shown and described with respect to certain preferred embodiments, the present invention is not restricted to the above-mentioned embodiments as a matter of course. It will be obvious to those skilled in the art that various changes may be made without departing from the scope of the invention.

Though the first to fourth embodiments describe that upper layer and the lower layer are formed of the same aluminum alloy containing at least one kind of Group 8 elements in the periodic table, they may be formed of a difference aluminum alloy containing at least one kind of Group 8 elements in the periodic table. This enables the formation of a conductive structure having high alkali resistance and high processing accuracy while suppressing the occurrence of a void with a simple structure. Each aluminum alloy containing at least one kind of Group 8 elements in the periodic table used for the upper layer and the lower layer may be selected according to usage.

When the laminated structure of the upper layer and the lower layer is used for a line, the Group 8 elements in the periodic table to form the lower layer may be an element that is not likely to cause an increase in line resistance. When it is used for a reflective layer, the Group 8 elements in the periodic table to form the lower layer may be an element having high reflectance. In order to achieve high manufacturing efficiently, it is preferred to use the same aluminum alloy containing at least one kind of Group 8 elements in the periodic table for both the upper layer and the lower layer as described in the first to fourth embodiments.

Though the first to fourth embodiments described above uses a TFT array substrate for a TFT liquid crystal display by way of illustration, the present invention is not limited thereto. The present invention may be applied to a different kind of element substrate such as a low-temperature polysilicon TFT array substrate and an organic EL array substrate and a conductive structure that is formed on an element substrate.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A conductive structure comprising:
a laminated structure of an upper layer and a lower layer, the lower layer formed of an aluminum alloy containing at least one kind of Group 8 elements in periodic table, and the upper layer laminated on the lower layer and formed of an aluminum alloy containing at least one kind of Group 8 elements in periodic table and nitrogen.

2. The conductive structure according to claim 1, wherein a thickness of the upper layer is between about 2 nm to about 50 nm.

3. The conductive structure according to claim 1, further comprising:
a conductive layer directly connected to the laminated structure, the conductive layer formed of a material containing at least one selected from indium oxide, tin oxide, and zinc oxide.

4. The conductive structure according to claim 3, wherein a thickness of the upper layer in a connection of the laminated structure and the conductive layer is smaller than a thickness of the upper layer in an area difference from the connection.

5. A method for manufacturing a conductive structure having a laminated structure of an upper layer and a lower layer, comprising:
forming the lower layer using an aluminum alloy containing at least one kind of Group 8 elements in periodic table;
forming the upper layer on the lower layer, using an aluminum alloy containing at least one kind of Group 8 elements in periodic table and nitrogen; and
patterning the upper layer and the lower layer of the laminated structure into a desired shape.

6. The method for manufacturing a conductive structure according to claim 5, wherein the patterning the upper layer and the lower layer patterns the upper layer and the lower layer of the laminated structure into a desired shape at the same time.

7. The method for manufacturing a conductive structure according to claim 5, wherein
the forming the lower layer forms the lower layer by sputtering using the aluminum alloy containing at least one kind of Group 8 elements in periodic table as a target; and
the forming the upper layer forms the upper layer by sputtering in a gas atmosphere containing nitrogen using the target.

8. The method for manufacturing a conductive structure according to claim 5, wherein
the forming the lower layer forms the lower layer by sputtering using the aluminum alloy containing at least one kind of Group 8 elements in periodic table as a target; and
the forming the upper layer forms the upper layer by sputtering using the aluminum alloy containing at least one kind of Group 8 elements in periodic table and nitrogen as a target.

9. An element substrate comprising:
a substrate;
a pixel electrode formed above the substrate;
a switching element formed above the substrate in corresponding to the pixel electrode and having a plurality of electrodes; and
a line formed above the substrate and connected to the switching element,
wherein the plurality of electrodes or the line has a laminated structure of an upper layer and a lower layer, the lower layer formed of an aluminum alloy containing at least one kind of Group 8 elements in periodic table, and the upper layer laminated on the lower layer and formed of an aluminum alloy containing at least one kind of Group 8 elements in periodic table and nitrogen.

10. The element substrate according to claim 9, wherein a thickness of the upper layer is between about 2 nm to about 50 nm.

11. The element substrate according to claim 9, wherein the pixel electrode is formed of a material containing at least one selected from indium oxide, tin oxide, and zinc oxide and directly connected to the laminated structure.

12. The element substrate according to claim 11, wherein a thickness of the upper layer in a connection of the laminated structure and the conductive layer is smaller than a thickness of the upper layer in an area different from the connection.

13. A method for manufacturing an element substrate including a substrate, a pixel electrode formed above the substrate, a switching element formed above the substrate in corresponding to the pixel electrode and having a plurality of electrodes, and a line formed above the substrate and connected to the switching element, the plurality of electrodes or the line having a laminated structure of an upper layer and a lower layer, the method comprising:
forming the lower layer using an aluminum alloy containing at least one kind of Group 8 elements in periodic table;
forming the upper layer on the lower layer, using an aluminum alloy containing at least one kind of Group 8 elements in periodic table and nitrogen;
patterning the upper layer and the lower layer of the laminated structure into a desired shape so that the laminated structure is connected to the switching element; and
forming the pixel electrode electrically connected to the laminated structure patterned into the desired shape.

14. The method for manufacturing an element substrate according to claim 13, wherein the patterning the upper layer and the lower layer patterns the upper layer and the lower layer of the laminated structure into a desired shape at the same time.

15. The method for manufacturing an element substrate according to claim 13, wherein
the forming the lower layer forms the lower layer by sputtering using the aluminum alloy containing at least one kind of Group 8 elements in periodic table as a target, and
the forming the upper layer forms the upper layer by sputtering in a gas atmosphere containing nitrogen using the target.

16. The method for manufacturing an element substrate according to claim 13, wherein
the forming the lower layer forms the lower layer by sputtering using the aluminum alloy containing at least one kind of Group 8 elements in periodic table as a target, and
the forming the upper layer forms the upper layer by sputtering using the aluminum alloy containing at least one kind of Group 8 elements in periodic table and nitrogen as a target.

17. The method for manufacturing an element substrate according to claim 13, wherein the pixel electrode is formed of a material containing at least one selected from indium oxide, tin oxide, and zinc oxide.
